(19) United States
(12) Patent Application Publication
(10) Pub. No.: US 2011/0204412 A1
(43) Pub. Date: Aug. 25, 2011

(54) METHOD FOR MANUFACTURING SEMICONDUCTOR LIGHT EMITTING ELEMENT

(75) Inventor: Susumu Sugano, Ichihara-shi (JP)

(73) Assignee: SHOWA DENKO K.K., Minato-ku, Tokyo (JP)

(21) Appl. No.: 13/126,136

(22) PCT Filed: Oct. 23, 2009
(86) PCT No.: PCT/JP2009/068250

§ 371 Date: Apr. 26, 2011

(30) Foreign Application Priority Data
Oct. 27, 2008 (JP) 2008-275683

(51) Int. Cl. H01L 33/32; H01L 21/78

(52) U.S. Cl. 257/103; 438/33; 257/E33.023; 257/E21.599

(57) ABSTRACT

Provided is a method for manufacturing a semiconductor light emitting element, by which semiconductor light emitting elements having excellent light extraction efficiency can be manufactured at high yield. The method includes: a grinding step for grinding a surface to be ground (103) of a substrate (11) of a wafer having the substrate (11) and group III nitride semiconductor layers composed of a multilayer structure of a group III nitride semiconductor formed on the substrate (11); a polishing step for adjusting surface roughness (Ra) of the ground surface (103) of the substrate (11) ground by the grinding step to be 3 nm to 25 nm; a laser processing step for providing processed modified portions (41, 42) inside of the substrate (11) by applying a laser beam (L2) along a cut-planned line for dividing the substrate (11) from the side of the ground surface (103) of the substrate (11) having the surface roughness (Ra) adjusted by the polishing step; and a dividing step for dividing the substrate (11) provided with the processed modified portions (41, 42) by the laser processing step, along the processed modified portions (41, 42) and the cut-planned line.

### TECHNICAL FIELD

The present invention relates to a method for manufacturing a semiconductor light emitting element, and the like, more particularly, to a method for manufacturing a semiconductor light emitting element including a group III nitride semiconductor, and the like.

### BACKGROUND ART

Recently, a group III nitride semiconductor has become a focus of attention as a material for a semiconductor light emitting element. A film of a group III nitride semiconductor is formed on a substrate of sapphire or the like by metal organic chemical vapor deposition (MOCVD method), molecular beam epitaxy (MBE method) or the like.

As a method to improve light extraction efficiency of a semiconductor light emitting element using such a group III nitride semiconductor, a method to reduce a phenomenon in which light is trapped inside of a light emitting element has been proposed. Such a trap of light occurs due to the difference in refractive indices between the light emitting element and a medium outside thereof.

For example, Patent Literature 1 describes a light emitting element provided with a novel structure to cause light in the lateral direction generated in a light emitting layer to turn outside. The light emitting element is provided by the following procedure: a surface of a substrate is processed to give unevenness; a layer having a refractive index different from that of the substrate is grown with the unevenness embedded therein; an interface of refractive indices having the unevenness is thereby formed; and thereafter, an element structure is formed in which semiconductor crystal layers including the light emitting layer are layered on the interface.

Meanwhile, Patent Literature 2 describes a nitride-based compound semiconductor light emitting element having a translucent electrode whose extraction efficiency of light from a side surface of a substrate is improved by providing unevenness on the rear surface of the substrate and by reflecting light toward the side surface of the substrate.

On the other hand, in Patent Literature 3, a compound semiconductor light emitting element wafer includes multiple compound semiconductor light emitting elements continuously arrayed with regularity on a substrate with separation bands interposed therebetween. This wafer is pushed and broken from the side of the sapphire substrate through a process for forming a dividing groove by a laser method in the separation bands on the surface on which a protective film is formed. Thereby, individual chip-like compound semiconductor light emitting elements are separated.

Furthermore, Patent Literature 4 proposes, as a method for dividing a wafer into individual elements, a method including: forming a modified region by irradiating the inside of the substrate of the wafer having semiconductor layers layered thereon with a laser beam having a correct focus; forming a starting region of cutting by using this modified region; and cutting the wafer along the starting region of cutting. In this case, it is necessary to obtain the accurate focus of the laser beam in order to form the modified region at a predetermined position in the substrate.

Additionally, it is known that if the film thickness of semiconductor layers is 5 μm or more, as the film thickness of the semiconductor layers increases, warping of a wafer after substrate thinning becomes larger due to the difference in thermal expansion coefficients between the semiconductor layers and the substrate (see Patent Literature 4). Such warping of the wafer may be adjusted to some extent by adjusting surface roughness (Ra) of the rear surface of the substrate, and is considered to be effective to maintain flatness of the substrate.

### CITATION LIST

### Patent Literature

Patent Literature 1: Japanese Patent Application Laid Open Publication No. 2002-280611

Patent Literature 2: Japanese Patent Application Laid Open Publication No. 2002-368261

Patent Literature 3: Japanese Patent Application Laid Open Publication No. 2005-109432

Patent Literature 4: Japanese Patent Application Laid Open Publication No. 2005-333122

### SUMMARY OF INVENTION

### Technical Problem

However, when a laser beam is applied from the rear surface side of a substrate, if the surface roughness (Ra) of the rear surface is excessively increased by unevenness formed on the rear surface of the substrate in order to maintain flatness of the substrate or to improve light extraction efficiency of a semiconductor light emitting element, as described above, it becomes difficult to obtain the accurate focus of the laser beam. Thus, a modified region cannot be accurately formed inside of the substrate of a wafer, which results in a problem of high occurrence of defective chips.

An object of the present invention is to provide a method for manufacturing a semiconductor light emitting element, and the like, by which semiconductor light emitting elements having excellent light extraction efficiency can be manufactured at high yield.

### SOLUTION TO PROBLEM

According to the present invention, there is provided a method for manufacturing a semiconductor light emitting element having group III nitride semiconductor layers. The method includes: a grinding step for grinding a surface to be ground of a substrate of a wafer having the substrate and the group III nitride semiconductor layers composed of a multilayer structure of a group III nitride semiconductor formed on the substrate; a polishing step for adjusting surface roughness Ra of the ground surface of the substrate ground by the grinding step to be 3 nm to 25 nm; a laser processing step for providing a processed modified portion for an inside of the substrate by applying a laser beam along a cut-planned line for dividing the substrate from the side of the ground surface of the substrate having the surface roughness Ra adjusted by the polishing step; and a dividing step for dividing the substrate along the processed modified portion and the cut-planned line, the substrate being provided with the processed modified portion by the laser processing step.

Here, in the method for manufacturing a semiconductor light emitting element to which the present invention is applied, the laser processing step preferably provides plural the processed modified portions discontinuously in a thickness direction of the substrate.

The laser processing step preferably provides the processed modified portion in a range of two thirds of the inside of the substrate in a thickness direction from the side of the ground surface.

Additionally, in the laser processing step the substrate is preferably irradiated with a pulse of the laser beam.

Next, in the dividing step of the method for manufacturing a semiconductor light emitting element to which the present invention is applied, the substrate is preferably divided to turn a divided surface of the substrate into a rough surface.

The method preferably further includes a dividing-groove forming step for forming a dividing groove in the substrate by applying a laser beam along the cut-planned line from the side of the group III nitride semiconductor layers formed on the substrate.

The method for manufacturing a semiconductor light emitting element to which the present invention is applied preferably further includes a substrate processing step for forming plural convex portions on a surface of the substrate in advance.

Additionally, the method preferably further includes a buffer layer forming step for forming a buffer layer composed of a group III nitride semiconductor by sputtering on the surface of the substrate having the convex portions formed thereon.

In the method for manufacturing a semiconductor light emitting element to which the present invention is applied, the substrate is preferably selected from any one of sapphire and silicon carbide.

Additionally, the group III nitride semiconductor layers of the wafer are preferably composed of a multilayer of an n-type semiconductor layer, a light emitting layer and a p-type semiconductor layer that each includes a group III nitride compound semiconductor.

In the method for manufacturing a semiconductor light emitting element to which the present invention is applied, the substrate preferably has a maximum diameter of about 100 mm or more.

Furthermore, according to the present invention, there is provided a semiconductor light emitting element manufactured by the above method for manufacturing a semiconductor light emitting element.

### ADVANTAGEOUS EFFECTS OF INVENTION

According to the present invention, it is possible to manufacture semiconductor light emitting elements having excellent light extraction efficiency at high yield.

### BRIEF DESCRIPTION OF DRAWINGS

FIG. 1 is a cross-sectional view showing an example of a semiconductor light emitting element having group III nitride semiconductor layers;

FIG. 2 is a diagram illustrating the substrate having the plural convex portion formed thereon;

FIG. 3 is a diagram illustrating the substrate having the plural convex portion formed thereon;

FIGS. 4A to 4D are diagrams illustrating steps to manufacture a semiconductor light emitting element;

FIGS. 5A to 5C are diagrams illustrating steps to manufacture a semiconductor light emitting element; and

FIGS. 6A to 6C are diagrams illustrating steps to manufacture a semiconductor light emitting element.

### DESCRIPTION OF EMBODIMENTS

Hereinafter, a description will be given of an exemplary embodiment of the present invention. Note that the present invention is not limited to the following exemplary embodiment and may be implemented with various modifications within its scope. In addition, the drawings to be used are for illustrating the exemplary embodiment, and do not show actual dimensions.

### (Semiconductor Light Emitting Element I)

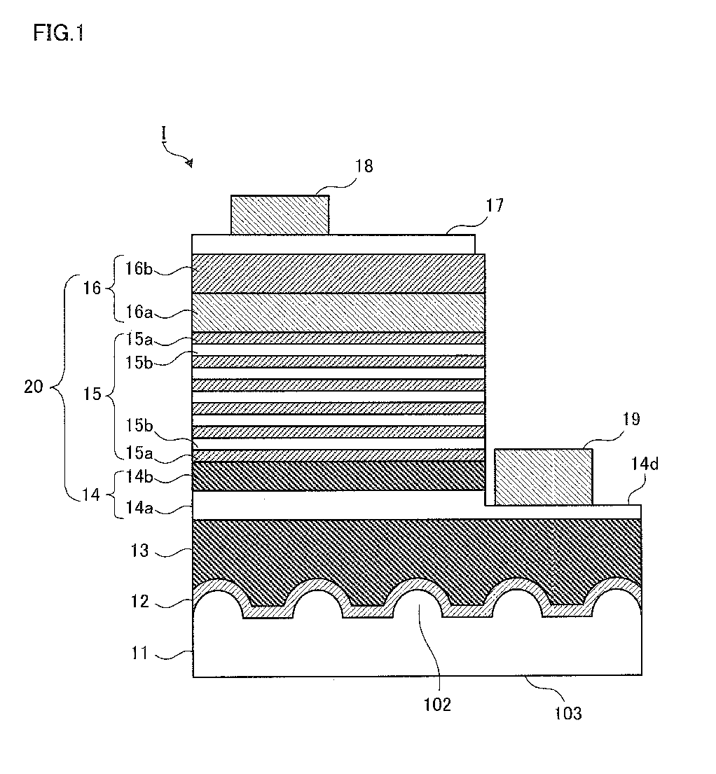

FIG. 1 is a cross-sectional view showing an example of a semiconductor light emitting element having group III nitride semiconductor layers. As shown in FIG. 1, a semiconductor light emitting element I has a structure including: a substrate 11 having plural convex portions 102 formed on a surface thereof; a buffer layer 12 formed on the surface of the substrate 11 on which the plural convex portions 102 are formed; a base layer 13 formed on the buffer layer 12 so as to embed the plural convex portions 102; and a LED structure 20 formed on the base layer 13.

In the LED structure 20, an n-type semiconductor layer 14, a light emitting layer 15 and a p-type semiconductor layer 16 are sequentially layered. The n-type semiconductor layer 14 composing the LED structure 20 has an n-type contact layer 14a and an n-type clad layer 14b. The light emitting layer 15 has a structure in which barrier layers 15a and well layers 15b are alternately layered. In the p-type semiconductor layer 16, a p-type clad layer 16a and a p-type contact layer 16b are layered.

Furthermore, a transparent positive electrode 17 is layered on the p-type semiconductor layer 16, and a positive electrode bonding pad 18 is formed on the transparent positive electrode 17. Meanwhile, a negative electrode 19 is layered on an exposed region 14d formed in the n-type contact layer 14a of the n-type semiconductor layer 14.

### (Substrate 11)

The substrate 11 is composed of a material different from a group III nitride compound semiconductor. Listed as examples of a material composing the substrate 11 are: sapphire, silicon carbide (SiC), silicon, zinc oxide, magnesium oxide, manganese oxide, zirconium oxide, zinc iron manganese oxide, magnesium aluminum oxide, zirconium boride, gallium oxide, indium oxide, lithium gallium oxide, lithium aluminum oxide, neodymium gallium oxide, lanthanum strontium aluminum tantalum oxide, strontium titanium oxide, titanium oxide, hafnium, tungsten, molybdenum, and the like. Among these materials, sapphire and silicon carbide (SiC) are preferable, and sapphire is particularly preferable.

In the present exemplary embodiment, a surface to be ground 103 of the substrate 11 is ground by a predetermined grinding device, and is then polished by a polishing device, as described later. Thereby, the thickness of the substrate 11 is adjusted generally to 170 μm or less and preferably to 160 μm or less. However, the thickness of the substrate 11 is not less than 70 μm in general.

Additionally, in the present exemplary embodiment, surface roughness Ra of the ground surface 103, which is the rear surface of the substrate 11, is adjusted from 3 nm to 25 nm and preferably from 5 nm to 20 nm.

Adjusting the rear surface of the substrate 11 to be a rough surface having surface roughness Ra in the above range leads to reducing warping of the substrate 11 and maintaining flatness of the substrate 11.

Light extraction efficiency of the semiconductor light emitting element I is increased by diffuse reflection of light on the ground surface 103.

Furthermore, a modified region is formed inside of the substrate 11, as described later. This makes it possible to obtain the accurate focus of a laser beam when the laser beam is applied from the side of the ground surface 103 of the substrate 11.

### (Plural Convex Portions 102)

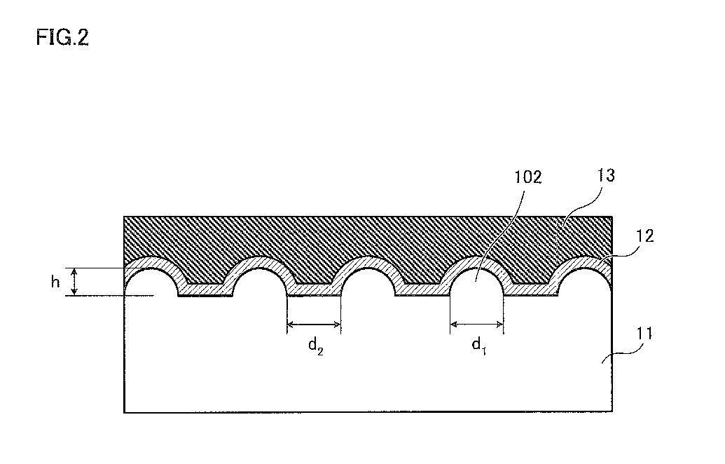

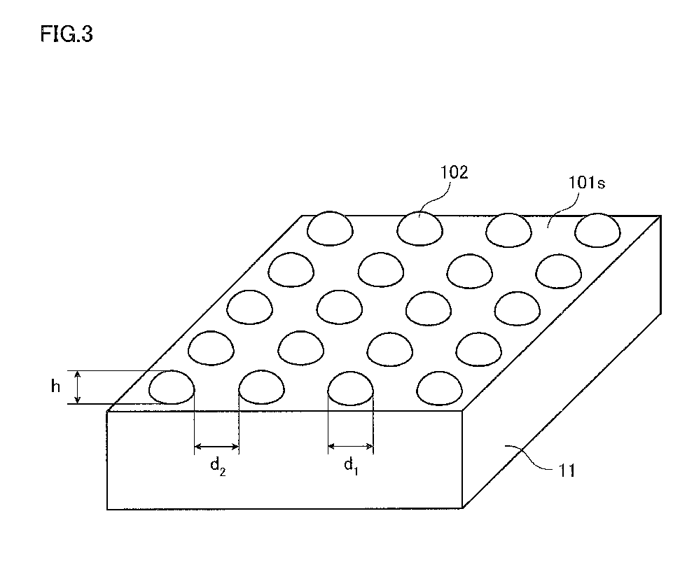

FIGS. 2 and 3 are diagrams illustrating the substrate 11 having the plural convex portions 102 formed thereon. As shown in FIG. 2, the plural convex portions 102 formed on the substrate 11 each have a predetermined maximum diameter d₁ and a predetermined height h, and are formed so as to have a uniform size and a uniform shape. In the present exemplary embodiment, each of the convex portions 102 has a hemispheric shape. Note that the shape of the convex portions 102 is not particularly limited.

In the present exemplary embodiment, the maximum diameter d₁ of the convex portions 102 is in a range of 0.5 μm to 2 μm. The height h of the convex portions 102 is in a range of 0.5 μm to 2 μm. Additionally, the plural convex portions 102 are arranged on the surface of the substrate 11 at predetermined distances d₂. In the present exemplary embodiment, the distance d₂ of the plural convex portions 102 is in a range of 0.5 μm to 2 μm.

Additionally, as shown in FIG. 3, the plural convex portions 102 are arranged on a surface 101, of the substrate 11 in a grid pattern at regular intervals.

In the present exemplary embodiment, the interface between the substrate 11 and the base layer 13 is provided with unevenness by forming the plural convex portions 102 having a uniform shape on the substrate 11. Thus, the light extraction efficiency of the semiconductor light emitting element I provided with the LED structure 20 on the substrate 11 having the above structure is further increased by diffuse reflection of light on the interface.

### (Buffer Layer 12)

The buffer layer 12 is provided on the substrate 11 as a thin film layer having a buffer function, when compound semiconductor layers having the LED structure of the semiconductor light emitting element are formed by metal organic chemical vapor deposition (MOCVD), as described later. Provision of the buffer layer 12 allows the base layer 13 formed on the buffer layer 12 and the compound semiconductor layers further formed thereon having the LED structure 20 to be crystal films having favorable orientation and crystallinity.

It is preferable for the group III nitride semiconductor composing the buffer layer 12 to contain Al, and is particularly preferable to contain AlN, which is group III nitride. The material composing the buffer layer 12 is not particularly limited as long as the material is a group III nitride semiconductor expressed by a general formula AlGaInN. Furthermore, the material may contain As or P as a group V element. When the composition of the buffer layer 12 includes Al, it is preferable for the buffer layer 12 to be AlGaN, and is preferable for the composition of Al to be 50% or more.

In the present exemplary embodiment, the thickness of the buffer layer 12 is 0.01 μm to 0.5 μm. If the thickness of the buffer layer 12 is excessively thin, an effect to reduce the difference in lattice constants between the substrate 11 and the base layer 13 may not be sufficiently obtained by the buffer layer 12. If the thickness of the buffer layer 12 is excessively thick, processing time for film formation tends to be longer and thus productivity tends to decrease.

### (Base Layer 13)

As a material for the base layer 13, group III nitride including Ga (a GaN-based compound semiconductor) is used. In particular, AlGaN or GaN is preferably used. The base layer 13 in the present exemplary embodiment functions as a base layer of the compound semiconductor layers having the LED structure 20.

In the present exemplary embodiment, the thickness of the base layer 13 is 0.1 μm or more, preferably 0.5 μm or more, and more preferably 1 μm or more. However, the thickness of the base layer 13 is not more than 10.0 μm in general.

### (LED Structure 20)

As described above, the n-type semiconductor layer 14 composing the LED structure 20 has the n-type contact layer 14a and the n-type clad layer 14b. The light emitting layer 15 has a structure in which the barrier layers 15a and the well layers 15b are alternately layered. In the p-type semiconductor layer 16, the p-type clad layer 16a and the p-type contact layer 16b are layered.

### (N-type Semiconductor Layer 14)

As the n-type contact layer 14a of the n-type semiconductor layer 14, a GaN-based compound semiconductor is used, similarly to the base layer 13. It is preferable that the gallium nitride-based compound semiconductor composing the base layer 13 have the same composition as the one composing the n-type contact layer 14a. The total film thickness of these layers is preferably set in a range of 0.1 μm to 20 μm, preferably 0.5 μm to 15 μm, and more preferably 1 μm to 12 μm.

The n-type clad layer 14b can be formed of AlGaN, GaN, GaInN or the like. Additionally, a structure obtained by heterojunction of structures of these compounds or a superlattice structure obtained by layering structures of these compounds several times may be employed. If GaInN is employed, it is desirable that the band gap of the n-type clad layer 14b be set larger than that of the GaInN of the light emitting layer 15. The film thickness of the n-type clad layer 14b is preferably in a range of 5 nm to 500 nm, and more preferably 5 nm to 100 nm.

### (Light Emitting Layer 15)

The light emitting layer 15 includes the barrier layers 15a composed of a gallium nitride-based compound semiconductor and the well layers 15b composed of a gallium nitride-based compound semiconductor containing indium, and these layers are alternately and repeatedly layered. In addition, the light emitting layer 15 is formed by layering in such an order that the barrier layers 15a are arranged on the n-type semiconductor layer 14 side and the p-type semiconductor layer 16 side. In the present exemplary embodiment, the light emitting layer 15 has the following configuration: six barrier layers 15a and five well layers 15b are alternately and repeatedly layered; the barrier layers 15a are arranged at the uppermost layer and the lowermost layer of the light emitting layer 15; and each well layer 15b is arranged between one barrier layer 15a and the next.

For the barrier layers 15a, a gallium nitride-based compound semiconductor, such as Al_{c}Ga_{1-c}N (where 0·c·0.3) or the like, having larger band gap energy than the well layers 15b composed of a gallium nitride-based compound semiconductor containing indium, for example, can be preferably used.

For the well layers 15b, gallium indium nitride, such as Ga₁₋ₛInₛN (where 0<s<0.4), for example, can be used as a gallium nitride-based compound semiconductor containing indium.

### (P-type Semiconductor Layer 16)

The p-type semiconductor layer 16 is composed of the p-type clad layer 16a and the p-type contact layer 16b. For the p-type clad layer 16a, Al_{d}Ga_{1-d}N (where 0<d<0.4) is preferably taken as an example. The film thickness of the p-type clad layer 16a is preferably 1 nm to 400 nm, and more preferably 5 nm to 100 nm.

For the p-type contact layer 16b, at least a gallium nitride-based compound semiconductor layer including AlₑGa₁₋ₑN (where 0<e<0.5) is taken as an example. The film thickness of the p-type contact layer 16b is not particularly limited, but is preferably 10 nm to 500 nm, and more preferably 50 nm to 200 nm.

### (Transparent Positive Electrode 17)

Listed as examples of a material composing the transparent positive electrode 17 are: ITO (In₂O₃—SnO₂), AZO (ZnO—Al₂O₃), IZO (In₂O₃—ZnO), GZO (ZnO—Ga₂O₃), and the like, which are conventionally known materials. The structure of the transparent positive electrode 17 is not particularly limited, and a conventionally known structure can be employed. The transparent positive electrode 17 may be formed so as to cover almost all the surface of the p-type semiconductor layer 16, or may have a grid form or a tree-like form.

### (Positive Electrode Bonding Pad 18)

The positive electrode bonding pad 18 serving as an electrode formed on the transparent positive electrode 17 is composed of a conventionally known material, such as Au, Al, Ni and Cu, for example. The structure of the positive electrode bonding pad 18 is not particularly limited, and a conventionally known structure can be employed.

The thickness of the positive electrode bonding pad 18 is in a range of 100 nm to 1000 nm, and preferably 300 nm to 500 nm.

### (Negative Electrode 19)

As shown in FIG. 1, the negative electrode 19 is formed so as to be in contact with the n-type contact layer 14a of the n-type semiconductor layer 14, in the films of the LED structure 20 (the n-type semiconductor layer 14, the light emitting layer 15 and the p-type semiconductor layer 16) further formed on the buffer layer 12 and the base layer 13 formed on the substrate 11. For this reason, when the negative electrode 19 is formed, a part of the p-type semiconductor layer 16, the light emitting layer 15 and the n-type semiconductor layer 14 is removed. Then, the exposed region 14d of the n-type contact layer 14a is formed, and the negative electrode 19 is formed thereon.

Negative electrodes having various compositions and structures are well known as a material for the negative electrode 19. These well-known negative electrodes can be used without any limitations, and can be provided by a conventional method well known in the art.

### (Method for Manufacturing Semiconductor Light Emitting Element)

Next, a description is given of a method for manufacturing a semiconductor light emitting element to which the present exemplary embodiment is applied.

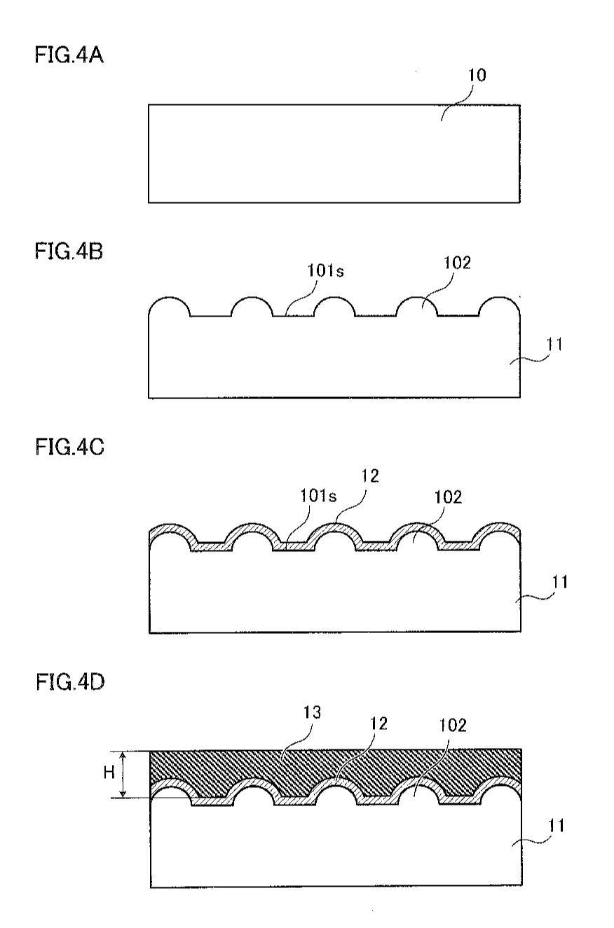

FIGS. 4A to 6C are diagrams illustrating steps to manufacture a semiconductor light emitting element.

As shown in FIG. 4A, a sapphire board 10 is first prepared. The maximum diameter of the sapphire board 10 is generally in a range of about 50 mm or more, preferably about 100 mm or more and more preferably about 50 mm to about 200 mm. The thickness is preferably in a range of 0.4 mm to 2 mm.

In the present exemplary embodiment, (1) a sapphire board 10 having a maximum diameter of about 50 mm and a thickness of 0.7 mm, (2) a sapphire board 10 having a maximum diameter of about 100 mm and a thickness of 1 mm and (3) a sapphire board 10 having a maximum diameter of about 150 mm and a thickness of 1.3 mm are used.

Next, as shown in FIG. 4B, the substrate 11 is processed to form the plural convex portions 102 having a uniform shape on the surface of the sapphire board 10 (substrate processing step). The processing of the substrate 11 includes: patterning to form a mask defining the planar layout of the convex portions 102 on the substrate 11; and etching the substrate 11 to form the convex portions 102 by use of the mask formed by the patterning. The patterning may be performed by a general photolithography method. The etching is preferably performed by use of a dry etching method.

Note that the method to form the convex portions 102 is not limited to the above-described etching method. For example, a material to be the convex portions 102 may be layered on the sapphire board 10 by a sputtering method, an evaporation method, a CVD method or the like, to form the convex portions. In this case, a material having nearly the same refractive index as the sapphire board 10 is preferably used as the material to be the convex portions 102. For example, Al₂O₃, SiN, SiO₂ or the like may be used.

Subsequently, as shown in FIG. 4C, the buffer layer 12 composed of a group III nitride semiconductor is formed on the surface 101ₛ of the substrate 11 (buffer layer forming step). In the present exemplary embodiment, the buffer layer 12 is preferably formed by sputtering a group III nitride semiconductor. When the buffer layer 12 is formed by sputtering, it is desirable to set the flow ratio of the nitrogen material to an inert gas in the chamber so that the nitrogen material is 50% to 100%, desirably 75%.

When the buffer layer 12 having a columnar crystal (polycrystalline) structure is formed by a sputtering method, it is desirable to set the flow ratio of the nitrogen material to an inert gas in the chamber so that the nitrogen material is 1% to 50%, desirably 25%. Thereby, the buffer layer 12 is formed as a single crystal structure, while nitrogen is used as a group V element and the gas fraction of nitrogen in the gas on the occasion of forming the buffer layer 12 is set in a range of 50% to 99%. As a result, in a short time, the buffer layer 12 having favorable crystallinity is formed on the substrate 11 as an orientation film having specific anisotropy. Additionally, a group III nitride semiconductor having favorable crystallinity may be formed on the buffer layer 12 with a high degree of efficiency.

Next, as shown in FIG. 4D, in the present exemplary embodiment, after the forming step of the buffer layer 12, the base layer 13 composed of a group III nitride semiconductor is formed by an MOCVD method on the top surface of the substrate 11 having the buffer layer 12 formed thereon so that the convex portions 102 are embedded. In the present exemplary embodiment, the maximum height H of the base layer 13 is preferably more than twice of the height h of the convex portions 102.

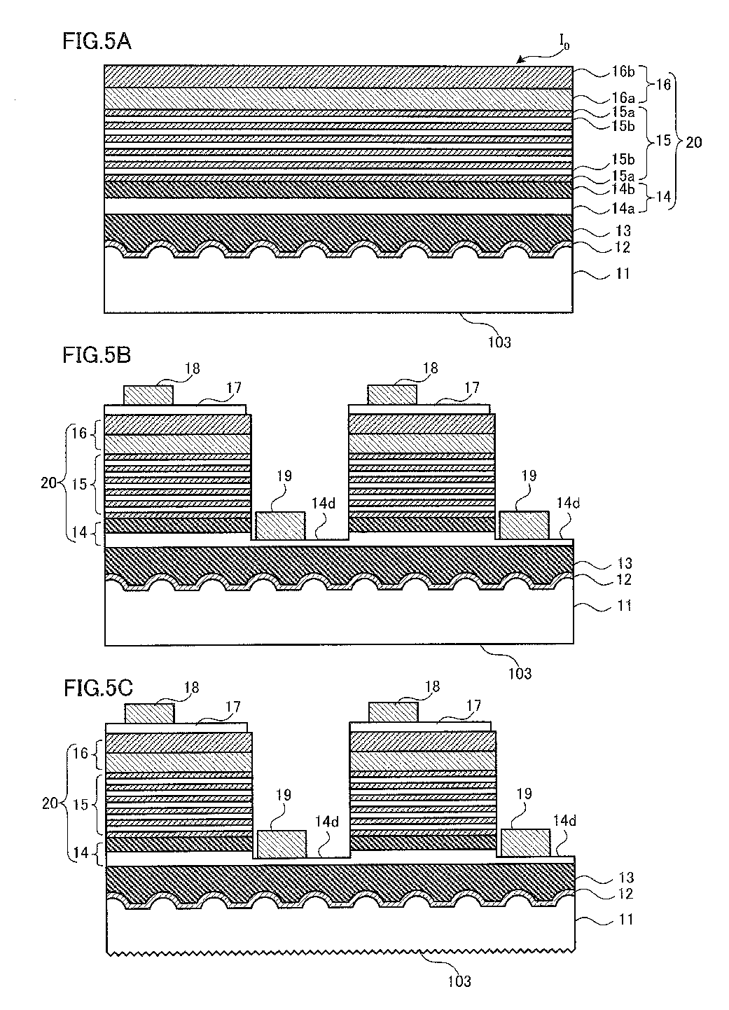

Next, as shown in FIG. 5A, the n-type semiconductor layer 14, the light emitting layer 15 and the p-type semiconductor layer 16 are sequentially layered on the formed base layer 13 by the MOCVD method, thereby to form a semiconductor light emitting element wafer I₀.

When the base layer 13 and the n-type semiconductor layer 14, the light emitting layer 15 and the p-type semiconductor layer 16 are layered by the MOCVD method, the following may be used for example: as a carrier gas, hydrogen (H₂) or nitrogen (N₃); as a Ga source being a group III material, trimethylgallium (TMG) or triethylgallium (TEG); as an Al source, trimethylaluminum (TMA) or triethylaluminium (TEA); as an In source, trimethylindium (TMI) or triethylindium (TEI); as an N source being a group V material, ammonium (NH₃) or hydrazine (N₂H₄).

For n-type dopant, monosilane (SiH₄) or disilane (Si₂H₆) may be used as an Si material, and germane gas (GeH₄) or an organic germanium compound, such as tetramethylgermanium ((CH₃)₄Ge) and tetraethylgermanium ((C₂H₅)₄Ge), may be used as a Ge material. For p-type dopant, biscyclopentadienylmagnesium (Cp₂Mg) may be used as an Mg material.

In the present exemplary embodiment, formation of the base layer 13 on the substrate 11 leads to favorable crystallinity of the LED structure 20 formed of the n-type semiconductor layer 14, the light emitting layer 15 and the p-type semiconductor layer 16 that are formed on the base layer 13 and composed of a group III nitride semiconductor. As a result, the semiconductor light emitting element I having excellent internal quantum efficiency and less leakage is obtained.

Note that after the base layer 13 is formed by the MOCVD method, the LED structure 20 may be formed in such a manner that each of the n-type contact layer 14a and the n-type clad layer 14b is formed by a sputtering method, the light emitting layer 15 on these layers is formed by the MOCVD method and each of the p-type clad layer 16a and the p-type contact layer 16b composing the p-type semiconductor layer 16 is formed by a reactive sputtering method.

Next, as shown in FIG. 5B, after the buffer layer 12, the base layer 13 and the LED structure 20 are formed on the substrate 11, the transparent positive electrode 17 is layered on the p-type semiconductor layer 16 of the LED structure 20 and then the positive electrode bonding pads 18 are formed thereon. Subsequently, predetermined positions of the LED structure 20 are removed by etching, and thereby the n-type semiconductor layer 14 is exposed to form the plural exposed regions 14d. The plural negative electrodes 19 are formed on the respective exposed regions 14d so as to be paired with the respective positive electrode bonding pads 18.

When the negative electrodes 19 are formed, portions of the p-type semiconductor layer 16, the light emitting layer 15 and the n-type semiconductor layer 14 that are formed on the substrate 11 are first removed by a method of dry etching or the like, thereby to form the exposed regions 14d of the n-type contact layer 14a. Then, on the exposed regions 14d, each material of Ni, Al, Ti and Au is sequentially layered, for example, from the surface side of the exposed regions 14d by a conventionally known method, thereby to form the negative electrodes 19 having a four-layer structure. Detailed illustration of the negative electrodes 19 is omitted.

Subsequently, as shown in FIG. 5C, the surface to be ground 103 of the substrate 11 is ground and polished until the substrate 11 has a predetermined thickness (grinding step and polishing step). In the present exemplary embodiment, the substrate 11 is ground by the grinding step for about 20 minutes, to reduce the thickness of the substrate 11 from about 1000 μm to about 120 μm, for example. In the present exemplary embodiment, the substrate 11 is further polished by the polishing step for about 15 minutes subsequent to the grinding step, to reduce the thickness of the substrate 11 from about 120 μm to about 80 μm.

Here, in the present exemplary embodiment, by the grinding step and the polishing step, the thickness of the substrate 11 is adjusted while the surface roughness Ra of the ground surface 103, which is the rear surface of the substrate 11, is adjusted from 3 nm to 25 nm and preferably from 5 nm to 20 nm.

The method to adjust the surface roughness Ra of the ground surface 103 to be in the above-described range is not particularly limited. For example, a method may be employed in which a grinding material or a polishing material is supplied at a portion where the ground surface 103 is rubbed against a ground surface of a grinding surface plate of a predetermined grinding or polishing device when the ground surface 103 of the substrate 11 is ground and polished. In this case, the type of the grinding material or the polishing material is not particularly limited, but a commercially available slurry grinding or polishing material may be used.

Additionally, in the present exemplary embodiment, the method to measure the surface roughness Ra is not particularly limited. For example, a conventionally known method by viewing angle analysis with an atomic force microscope (AFM), a scanning electron microscope (SEM) or the like may be used to obtain the surface roughness Ra as an arithmetic mean roughness Ra.

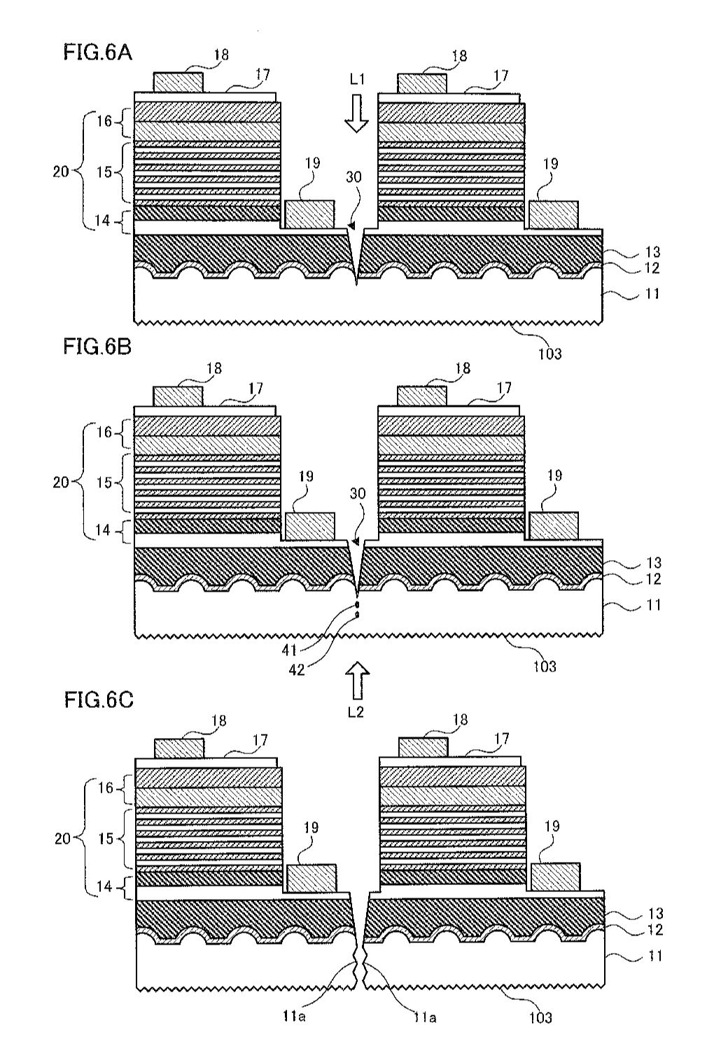

Next, as shown in FIG. 6A, the exposed region 14d of the n-type contact layer 14a is irradiated with a laser beam L1 from the side of the LED structure 20, to form a dividing groove 30 (dividing-groove forming step). The dividing groove 30 is formed by applying the laser beam L1 along a cut-planned line for dividing the substrate 11, as described later. The width of the dividing groove 30 is not particularly limited. In the present exemplary embodiment, the depth of the dividing groove 30 from the surface of the substrate 11 is generally 6 μm or more, preferably 10 μm or more, and more preferably 20 μm or more. If the depth of the dividing groove 30 is excessively small, the cut surface tends to be obliquely divided to give defective chips.

A rectangle, a U-shape or a V-shape is employed as the shape of the cross section of the dividing groove 30. Among these, a V-shape or a U-shape is preferable, and a V-shape is particularly preferable. Note that if the cross section of the dividing groove 30 has a V-shape, a crack may be generated from the vicinity of the cutting edge of the V-shape on the occasion of dividing into chips, and thus the defective rate tends to decrease. The shape of the cross section of the dividing groove 30 may be controlled by a control on a laser optical system, such as a control of the diameter of the beam and the position of the focus.

Subsequently, as shown in FIG. 6B, a laser beam L2 is applied along the cut-planned line for dividing the substrate 11 from the side of the ground surface 103 of the substrate 11 having the surface roughness Ra adjusted by the above-described polishing step, thereby to provide processed modified portions (inside cracks) 41 and 42 for the inside of the substrate 11 (laser processing step). In the present exemplary embodiment, the laser processing step provides the two processed modified portions 41 and 42 in a range of two thirds of the inside of the substrate 11 discontinuously in the thickness direction from the side of the ground surface.

Additionally, the processed modified portions 41 and 42 are formed on substantially the same straight line as the dividing groove 30 provided in the substrate 11 in the thickness direction of the substrate 11.

In the present exemplary embodiment, the processed modified portions 41 and 42 refer to, for example, a modified region where a portion of the substrate 11 irradiated with the laser beam L2 is molten and resolidified by irradiating the inside of the substrate 11 made of sapphire with the laser beam L2 having a correct focus, a modified region formed by multiple photon absorption, or the like. On this occasion, tiny cracks are also generated along with melting and resolidification due to irradiation of the laser.

Specifically, for example, a stealth laser processing machine (not shown) is used, and the laser beam L2 is applied along the cut-planned line for dividing the substrate 11 while a pulsed laser in excimer excitation is applied. On this occasion, processed modified portions (in FIG. 6B, the two processed modified portions 41 and 42) are provided at plural positions in the thickness direction of the substrate 11 by changing the focus of the laser beam L2 applied on the substrate 11.

As the laser to be used, a CO₂ laser, a YAG (yttrium aluminum garnet) laser and the like are listed as example. In the present exemplary embodiment, use of pulse irradiation of a laser is the most preferable. In the present exemplary embodiment, the laser beam L2 having a wavelength of 266 nm or 355 nm is used. Additionally, intermittent application of the laser beam L2 (pulse irradiation) along the cut-planned line of the substrate 11 causes damage to the inside of the substrate 11 in an effective manner, thereby to volatilize this portion or to turn this portion into a material having low intensity. In this case, the pulse period is preferably set in a range of 10 Hz to 40 Hz.

Next, as shown in FIG. 6C, the substrate 11 is cut along the processed modified portions 41 and 42, to divide into plural chips (dividing step). Specifically, for example, a blade (not shown) is pressed along the dividing groove 30 and the processed modified portions 41 and 42 by using a breaking device (not shown), thereby to push and break the substrate 11 along the processed modified portions 41 and 42 to divide the substrate 11 into plural chips.

In the present exemplary embodiment, the substrate 11 is divided into chips corresponding to respective individual light emitting elements along the dividing groove 30 and the processed modified portions 41 and 42 in the dividing step. A crack is then generated in the substrate 11 with the processed modified portions 41 and 42 as starting points, and thereby the semiconductor light emitting element wafer I₀ (see FIG. 5A) is divided into the semiconductor light emitting elements I as individual chips.

At this time, in the divided surface (end face 11a) of the divided substrate 11, there exist a region where at least a part of the processed modified portions 41 and 42 remains and a region with an irregularly remaining scar of the crack generated in the divided surface (end face 11a) when the substrate 11 is cut. Thus, almost the whole divided surface (end face 11a) becomes a rough surface.

As described above, formation of the divided surface (end face 11a) of the substrate 11 as a rough surface increases the surface area of the divided surface (end face 11a). Thus, light incident on the substrate 11 is emitted outside with a high degree of efficiency. The semiconductor light emitting element I having excellent light extraction efficiency may be manufactured by using the substrate 11 having the divided surface (end face 11a) thus formed as a rough surface.

In the present exemplary embodiment, in general, the films of the LED structure 20 are formed on the substrate 11; the substrate 11 is then adjusted in the grinding and polishing steps for the ground surface 103 so as to have a predetermined thickness; the substrate 11 is thereafter cut into an appropriate size; and thereby group III nitride semiconductor light emitting elements are obtained as semiconductor light emitting element chips having the substrate 11 with a predetermined thickness.

In the present exemplary embodiment, the difference in thermal expansion coefficients between the semiconductor layers and the substrate affects warping of the wafer after substrate thinning. In particular, if the film thickness of the semiconductor layers including the light emitting layer is 5 μm or more, the warping becomes larger as the film thickness of the semiconductor layers increases. This adversely affects the subsequent laser processing step.

However, according to the method for manufacturing a semiconductor light emitting element to which the present exemplary embodiment is applied, the surface roughness Ra of the ground surface of the substrate ground in the grinding step is adjusted from 3 nm to 25 nm in the polishing step, thereby to maintain flatness of the substrate in the laser processing step.

Such an effect becomes more significant as the maximum diameter of the substrate, for example, that of the sapphire substrate increases. The present exemplary embodiment represents particular effectiveness in order of the maximum diameter being about 50 mm<about 100 mm<about 150 mm.

As described above, the semiconductor light emitting element I to which the present exemplary embodiment is applied is used for a lamp configured by a combination with phosphor, for example. A lamp of a combination of the semiconductor light emitting element I and phosphor has a configuration that is well known to those skilled in the art and is obtained by a method well known to those skilled in the art. A combination of a group III nitride semiconductor light emitting element and phosphor allows for employing a technique to change colors of light emission. Listed as examples of the lamp are a bullet-shaped type for a general purpose, a side-view type for use of a backlight of a cellular phone, a top-view type for use of an indicator, and the like. The lamp may be used for plural application purposes.

### REFERENCE SIGNS LIST

10 . . . sapphire board
11 . . . substrate
11a . . . divided surface (end face)
12 . . . buffer layer
13 . . . base layer
14 . . . n-type semiconductor layer
15 . . . light emitting layer
16 . . . p-type semiconductor layer
17 . . . transparent positive electrode
18 . . . positive electrode bonding pad
19 . . . negative electrode
20 . . . LED structure
30 . . . dividing groove
41, 42 . . . processed modified portion (inside crack)
102 . . . convex portion
103 . . . ground surface
I . . . semiconductor light emitting element

1. A method for manufacturing a semiconductor light emitting element having group III nitride semiconductor layers, the method comprising:
a grinding step for grinding a surface to be ground of a substrate of a wafer having the substrate and the group III nitride semiconductor layers composed of a multilayer structure of a group III nitride semiconductor formed on the substrate;
a polishing step for adjusting surface roughness Ra of the ground surface of the substrate ground by the grinding step to be 3 nm to 25 nm;
a laser processing step for providing a processed modified portion for an inside of the substrate by applying a laser beam along a cut-planned line for dividing the substrate from the side of the ground surface of the substrate having the surface roughness Ra adjusted by the polishing step; and
a dividing step for dividing the substrate along the processed modified portion and the cut-planned line, the substrate being provided with the processed modified portion by the laser processing step.

2. The method for manufacturing a semiconductor light emitting element according to claim 1, wherein the laser processing step provides a plurality of the processed modified portions discontinuously in a thickness direction of the substrate.

3. The method for manufacturing a semiconductor light emitting element according to claim 1, wherein the laser processing step provides the processed modified portion in a range of two thirds of the inside of the substrate in a thickness direction from the side of the ground surface.

4. The method for manufacturing a semiconductor light emitting element according to claim 1, wherein in the laser processing step the substrate is irradiated with a pulse of the laser beam.

5. The method for manufacturing a semiconductor light emitting element according to claim 1, wherein in the dividing step the substrate is divided to turn a divided surface of the substrate into a rough surface.

6. The method for manufacturing a semiconductor light emitting element according to claim 1, further comprising a dividing-groove forming step for forming a dividing groove in the substrate by applying a laser beam along the cut-planned line from the side of the group III nitride semiconductor layers formed on the substrate.

7. The method for manufacturing a semiconductor light emitting element according to claim 1, further comprising a substrate processing step for forming a plurality of convex portions on a surface of the substrate in advance.

8. The method for manufacturing a semiconductor light emitting element according to claim 7, further comprising a buffer layer forming step for forming a buffer layer composed of a group III nitride semiconductor by sputtering on the surface of the substrate having the convex portions formed thereon.

9. The method for manufacturing a semiconductor light emitting element according to claim 1, wherein the substrate is selected from any one of sapphire and silicon carbide.

10. The method for manufacturing a semiconductor light emitting element according to claim 1, wherein the group III nitride semiconductor layers of the wafer are composed of a multilayer of an n-type semiconductor layer, a light emitting layer and a p-type semiconductor layer that each includes a group III nitride compound semiconductor.

11. The method for manufacturing a semiconductor light emitting element according to claim 1, wherein the substrate has a maximum diameter of about 100 mm or more.

12. A semiconductor light emitting element manufactured by the method for manufacturing a semiconductor light emitting element according to claim 1.
